(19) United States
(12) Patent Application Publication
(10) Pub. No.: US 2026/0292990 A1
(43) Pub. Date: Sep. 24, 2026

(54) METHOD FOR MANUFACTURING CIRCUIT CONNECTION STRUCTURE, ADHESIVE FILM FOR CIRCUIT CONNECTION, AND CIRCUIT CONNECTION STRUCTURE

(71) Applicant: Resonac Corporation, Minato-ku, Tokyo (JP)

(72) Inventors: Kazuya NARITOMI, Tokyo (JP); Takayuki ICHIMURA, Tokyo (JP); Tomoharu YAMAZAKI, Tokyo (JP)

(21) Appl. No.: 19/479,506

(22) PCT Filed: Oct. 2, 2024
(86) PCT No.: PCT/JP2024/035288

§ 371 Date: Oct. 28, 2025

(30) Foreign Application Priority Data
Nov. 9, 2023 (JP) 2023-191588

(51) Int. Cl. H05K 1/14; H05K 3/36

(52) U.S. Cl. CPC H05K 1/144; H05K 3/368; H05K 2201/0195; H05K 2201/041

(57) ABSTRACT

A method for producing a circuit connection structure includes a step of interposing an adhesive film for circuit connection containing conductive particles between a first circuit member having a first electrode and a second circuit member having a second electrode, and thermocompression-bonding the first circuit member and the second circuit member to electrically connect the first electrode and the second electrode to each other. The adhesive film for circuit connection has a first adhesive layer containing conductive particles and a first thermosetting resin component, and a second adhesive layer disposed on the first adhesive layer and containing a second thermosetting resin component. The second thermosetting resin component includes a cationically polymerizable compound, a thermal cationic polymerization initiator, and a cation stabilizer that reacts with a cation species generated by thermal decomposition of the thermal cationic polymerization initiator.

### TECHNICAL FIELD

The present disclosure relates to a method for producing a circuit connection structure, an adhesive film for circuit connection, and a circuit connection structure.

### BACKGROUND ART

Liquid crystal display panels, organic EL panels, and the like have been used as various display means for televisions, PC monitors, mobile phones, smartphones, and the like. Such display devices employ “COG (chip on glass) mounting”, in which a driver IC is mounted directly on a glass substrate of a display panel, from the viewpoints of achieving a finer pitch, reductions in weight and thickness, and the like.

In a liquid crystal display panel in which the COG mounting method is employed, for example, a semiconductor element such as a liquid crystal driver IC is connected to a transparent substrate (e.g., a glass substrate) having a plurality of transparent electrodes (e.g., ITO (indium tin oxide)). As an adhesive material for connecting electrode terminals of the semiconductor element to the transparent electrodes, an adhesive film for circuit connection having anisotropic conductivity in which conductive particles are dispersed in the adhesive is used. For example, when a liquid crystal driver IC is mounted as a semiconductor element, the liquid crystal driver IC has, on its mounting surface, a plurality of electrode terminals corresponding to the transparent electrodes, and the electrode terminals and the transparent electrodes are connected by thermocompression-bonding the liquid crystal driver IC to the transparent substrate with the adhesive film for circuit connection having anisotropic conductivity interposed therebetween, thereby obtaining a circuit connection structure.

Displays having a curved surface (flexible displays), such as POELD (Plasitic Organic Electro-Luminescence Diode: organic light-emitting diode) displays, have been proposed. In such flexible displays, since a plastic substrate having flexibility (e.g., a polyimide substrate) is used as a substrate instead of a glass substrate, various electronic components such as a driver IC are also mounted on the plastic substrate. As a method for such mounting, COP (chip on plastic) mounting using an adhesive film for circuit connection having anisotropic conductivity has been studied (e.g., see Patent Literature 1).

### CITATION LIST

### Patent Literature

Patent Literature 1: Japanese Unexamined Patent Application Publication No. 2016-054288

### SUMMARY OF INVENTION

### Technical Problem

For OELDs, which are current-driven, a further reduction in connection resistance between opposing electrodes is required. On the other hand, in the case where mounting is performed using an adhesive film for circuit connection having anisotropic conductivity, it is also required that sufficient adhesion strength be exhibited under short-time mounting conditions.

A known method for reducing the connection resistance of a circuit connection structure is, for example, to adjust the particle hardness of the conductive particles or to lower the minimum melt viscosity of the adhesive film for the purpose of improving the contact between the electrodes and the conductive particles. However, by these methods alone, it is difficult to obtain a circuit connection structure in which the connection resistance value is unlikely to increase even after a reliability test under short-time mounting.

Accordingly, a primary object of the present disclosure is to provide a method for producing a circuit connection structure and an adhesive film for circuit connection, with which a circuit connection structure that is connected with sufficient adhesion strength and has excellent connection reliability can be obtained while the connection resistance value between opposing electrodes is reduced.

### Solution to Problem

One aspect of the present disclosure relates to [1] to [14] below.
[1] A method for producing a circuit connection structure, the method including a step of interposing an adhesive film for circuit connection containing conductive particles between a first circuit member having a first electrode and a second circuit member having a second electrode, and thermocompression-bonding the first circuit member and the second circuit member to electrically connect the first electrode and the second electrode to each other, wherein the adhesive film for circuit connection has a first adhesive layer comprising conductive particles and a first thermosetting resin component, and a second adhesive layer disposed on the first adhesive layer, the second adhesive layer comprising a second thermosetting resin component, and wherein the second thermosetting resin component includes a cationically polymerizable compound, a thermal cationic polymerization initiator, and a cation stabilizer that reacts with a cation species generated by thermal decomposition of the thermal cationic polymerization initiator.
[2] The method for producing a circuit connection structure according to [1], wherein the cation stabilizer is at least one compound selected from the group consisting of a thiourea compound, a 4-alkylthiophenol compound, and a 4-hydroxyphenyl-dialkylsulfonium salt.
[3] The method for producing a circuit connection structure according to [1] or [2], wherein a content of the cation stabilizer in the second adhesive layer is 5 to 20 parts by mass, relative to 100 parts by mass of the thermal cationic polymerization initiator.
[4] The method for producing a circuit connection structure according to any of [1] to [3], wherein a content of the cation stabilizer in the second adhesive layer is 0.01% to 2.0% by mass, based on a total mass of the second adhesive layer.
[5] The method for producing a circuit connection structure according to any of [1] to [4], wherein the cationically polymerizable compound is at least one compound selected from the group consisting of an oxetane compound and an alicyclic epoxy compound.
[6] The method for producing a circuit connection structure according to any of [1] to [5], wherein the first thermosetting resin component includes a cationically polymerizable compound and a thermal cationic polymerization initiator, wherein the first adhesive layer further comprises a cured product of a photocurable resin component, and wherein the photocurable resin component includes a radically polymerizable compound and a photoradical polymerization initiator.
[7] The method for producing a circuit connection structure according to any of [1] to [6], wherein the first adhesive layer has a thickness of 5.0 μm or less.
[8] An adhesive film for circuit connection, the adhesive film including a first adhesive layer comprising conductive particles and a first thermosetting resin component, and a second adhesive layer disposed on the first adhesive layer, the second adhesive layer comprising a second thermosetting resin component, wherein the second thermosetting resin component includes a cationically polymerizable compound, a thermal cationic polymerization initiator, and a cation stabilizer that reacts with a cation species generated by thermal decomposition of the thermal cationic polymerization initiator.
[9] The adhesive film for circuit connection according to [8], wherein the cation stabilizer is at least one compound selected from the group consisting of a thiourea compound, a 4-alkylthiophenol compound, and a 4-hydroxyphenyl-dialkylsulfonium salt.
[10] The adhesive film for circuit connection according to [8] or [9], wherein a content of the cation stabilizer in the second adhesive layer is 5 to 20 parts by mass, relative to 100 parts by mass of the thermal cationic polymerization initiator.
[11] The adhesive film for circuit connection according to any of [8] to [10], wherein a content of the cation stabilizer in the second adhesive layer is 0.01% to 2.0% by mass, based on a total mass of the second adhesive layer.
[12] The adhesive film for circuit connection according to any of [8] to [11], wherein the cationically polymerizable compound is at least one compound selected from the group consisting of an oxetane compound and an alicyclic epoxy compound.
[13] The adhesive film for circuit connection according to any of [8] to [12], wherein the first thermosetting resin component includes a cationically polymerizable compound and a thermal cationic polymerization initiator, wherein the first adhesive layer further comprises a cured product of a photocurable resin component, and wherein the photocurable resin component includes a radically polymerizable compound and a photoradical polymerization initiator.
[14] The adhesive film for circuit connection according to any of [8] to [13], wherein the first adhesive layer has a thickness of 5.0 μm or less.
[15] A circuit connection structure including: a first circuit member having a first electrode; a second circuit member having a second electrode; and a circuit connection portion disposed between the first circuit member and the second circuit member, the circuit connection portion electrically connecting the first electrode and the second electrode to each other, wherein the circuit connection portion includes a cured body of the adhesive film for circuit connection according to any of [8] to [14].

According to the method for producing a circuit connection structure described in [1] above, a circuit connection structure that is connected with sufficient adhesion strength and has excellent connection reliability can be obtained while the connection resistance value between opposing electrodes is reduced. The reason why such an advantageous effect is achieved is considered to be that the use of the adhesive film for circuit connection having a second adhesive layer containing a cation stabilizer increases the reaction initiation temperature of cationic polymerization of the second adhesive layer, improving the resin exclusion properties at the time of connection and reducing the connection gap (the distance between the connected opposing electrodes), thereby increasing the contact area between the conductive particles and the electrodes.

### Advantageous Effects of Invention

According to the present disclosure, it is possible to provide a method for producing a circuit connection structure and an adhesive film for circuit connection, with which a circuit connection structure that is connected with sufficient adhesion strength and has excellent connection reliability can be obtained while the connection resistance value between opposing electrodes is reduced. The circuit connection structure obtained as described above may reduce the likelihood of an increase in the connection resistance value between opposing electrodes even after a reliability test conducted under a high-temperature, high-humidity environment.

Meanwhile, with increases in pixel density in recent displays, reductions in the electrode area and pitch of driver ICs have been advancing. In such cases, it becomes difficult to ensure insulation performance between adjacent electrodes while increasing the capture rate of conductive particles. In contrast, according to the method for producing a circuit connection structure and the adhesive film for circuit connection according to the present disclosure, since the connection resistance value between opposing electrodes can be reduced by reducing the above-described connection gap, it is possible to sufficiently address the reductions in electrode area and pitch.

### BRIEF DESCRIPTION OF DRAWINGS

FIG. 1 is a schematic cross-sectional view of one embodiment of an adhesive film for circuit connection.

FIG. 2 is a schematic cross-sectional view of one embodiment of a circuit connection structure.

FIG. 3 includes schematic cross-sectional views of one embodiment of a method for producing a circuit connection structure.

### DESCRIPTION OF EMBODIMENTS

Embodiments of the present disclosure will be described in detail below with reference to the drawings. In the following description, the same reference numerals are given to the same or corresponding parts, and redundant description is omitted. It should be noted that the present disclosure is not limited to the embodiments described below.

In this description, a numerical range indicated by “to” represents a range including numerical values described before and after “to” as minimum and maximum values, respectively. In a numerical range described stepwise in this description, an upper or lower limit of one stage of the numerical range may be replaced with an upper or lower limit of another stage of the numerical range. In a numerical range described in this description, an upper or lower limit of the numerical range may be replaced with a value shown in Examples. Individually described upper and lower limits can also be employed in any combination. In the notation of a numerical range “A to B”, the numerical values A and B at both ends are included in the numerical range as lower and upper limits, respectively. In this description, for example, the description “10 or more” means “10” and “a numerical value greater than 10”, and the same applies when the numerical value is different. For example, the description “10 or less” means “10” and “a numerical value less than 10”, and the same applies when the numerical value is different. In this description, “(meth)acrylate” means at least one of an acrylate and a corresponding methacrylate. The same applies to other similar expressions such as “(meth)acryloyl” and “(meth)acrylic acid”. “A or B” means that at least one of A and B is included, and both A and B may be included. The materials shown by way of example below may be used alone or in a combination of two or more unless otherwise specified. When a plurality of substances corresponding to each component is present in a composition, the content of the component in the composition means the total amount of the plurality of substances present in the composition unless otherwise specified.

### [Adhesive Film for Circuit Connection]

An adhesive film for circuit connection according to this embodiment includes a first adhesive layer containing conductive particles and a first thermosetting resin component, and a second adhesive layer disposed on the first adhesive layer, the second adhesive layer containing a second thermosetting resin component, wherein the second thermosetting resin component includes a cationically polymerizable compound, a thermal cationic polymerization initiator, and a cation stabilizer that reacts with a cation species generated by thermal decomposition of the thermal cationic polymerization initiator. The first adhesive layer may further contain a photocurable resin component. The photocurable resin component may include a radically polymerizable compound and a photoradical polymerization initiator.

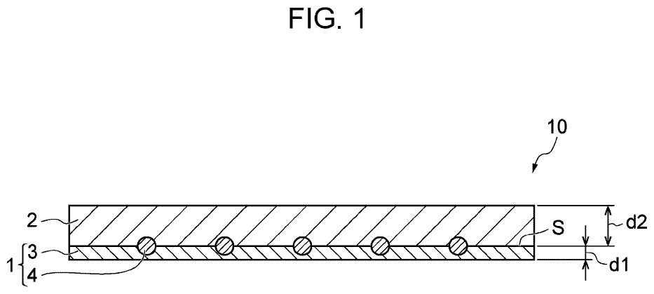

FIG. 1 is a schematic cross-sectional view of one embodiment of the adhesive film for circuit connection, and is a diagram schematically illustrating a vertical cross section of the adhesive film for circuit connection. The adhesive film for circuit connection 10 illustrated in FIG. 1 includes a first adhesive layer 1 containing a plurality of conductive particles 4 and an adhesive component 3, and a second adhesive layer 2 disposed on the first adhesive layer 1. In this description, “vertical cross section” means a cross section (a cross section in the thickness direction) orthogonal to a main surface (e.g., the adhesive film for circuit connection 10).

At least some of the plurality of conductive particles 4 may be arranged, in the vertical cross section of the adhesive film for circuit connection 10, in a lateral direction such that adjacent conductive particles are spaced apart from one another. Note that “lateral direction” means a direction (the horizontal direction in FIG. 1) parallel to the main surface of the adhesive film for circuit connection. While some of the conductive particles 4 are exposed at the surface of the first adhesive layer 1 (e.g., protruding toward the second adhesive layer 2) in FIG. 1, the entire conductive particles 4 may be embedded in the first adhesive layer 1 so as not to be exposed at the surface of the first adhesive layer 1 (the conductive particles 4 may be dispersed in the first adhesive layer 1).

The adhesive film for circuit connection 10 is an adhesive film for circuit connection having anisotropic conductivity (anisotropic conductive adhesive film), and may be interposed between a first circuit member having a first electrode and a second circuit member having a second electrode, and may be used for thermocompression-bonding the first and second circuit members to electrically connect the first and second electrodes to each other. Note that “anisotropic conductivity” means that conduction is established in a pressing direction, while insulating properties are maintained in a non-pressing direction.

Each component constituting the first adhesive layer 1 and the second adhesive layer 2 will be described next.

### <First Adhesive Layer>

The first adhesive layer 1 may contain, for example, conductive particles 4 (hereinafter, may be referred to as “component (A)”), a cured product of a photocurable resin component (hereinafter, may be referred to as “component (B)”), and a thermosetting resin component (hereinafter, may be referred to as “component (C)”). The cured product of the component (B) may be a cured product obtained by completely curing the component (B) and may also be a cured product obtained by partially curing the component (B). The component (C) is a component capable of flowing during connection, and is, for example, an uncured curable component (e.g., a resin component). Components constituting the first adhesive layer 1 other than the conductive particles 4 are, for example, components having no conductivity (e.g., insulating resin components).

### [Component (A): Conductive Particles]

The component (A) is not particularly limited and may be any particles having conductivity; it may be metal particles composed of metals such as Au, Ag, Pd, Ni, Cu, or solder, conductive carbon particles composed of conductive carbon, or the like. The component (A) may be coated conductive particles including a core containing non-conductive glass, ceramic, plastic (e.g., polystyrene), or the like and a coating layer containing the above metal or the above conductive carbon and coating the core. As the component (A), various kinds of conductive particles may be used alone or in a combination of two or more. Among these, the component (A) is preferably coated conductive particles including a core containing plastic and a coating layer containing a metal or conductive carbon and coating the core.

In the case where the component (A) is coated conductive particles, since it becomes easy to deform a cured product of the thermosetting resin component by heating or pressing, when the electrodes are electrically connected, the contact area between the electrodes and the component (A) can be increased, thereby further improving the conductivity between the electrodes.

The particle hardness of the component (A) may be 1,000 to 30,000 N/mm², and may also be 3,000 to 200,000 N/mm², from the viewpoint of reducing a connection gap. The particle hardness is a value measured at a measurement temperature of 25° C. using a micro-compression tester (probe tip shape: 50 μm×50 μm square).

The particle hardness of the component (A) may be 1,000 to 9,000 N/mm², and may also be 3,000 to 9,000 N/mm². In this case, the connection resistance value between opposing electrodes of the circuit connection structure is unlikely to increase even under a high-temperature, high-humidity environment. From the viewpoint of reducing the connection resistance value between opposing electrodes of the circuit connection structure, the particle hardness of the component (A) may be 10,000 to 200,000 N/mm², and may also be 10,000 to 30,0000 N/mm².

The maximum particle size of the component (A) needs to be smaller than the minimum spacing between electrodes (the shortest distance between adjacent electrodes). From the viewpoint of being excellent in terms of dispersibility and conductivity, the maximum particle size of the component (A) may be 1.0 μm or more, 2.0 μm or more, or 2.5 μm or more. From the viewpoint of being excellent in terms of dispersibility and conductivity, the maximum particle size of the component (A) may be 30.0 μm or less, 25.0 μm or less, 20.0 μm or less, 15.0 μm or less, 10.0 μm or less, or 5.0 μm or less. In this description, the particle sizes of any 300 particles (pcs) of the component (A) in the first adhesive layer are measured by observation using a scanning electron microscope (SEM), and the largest value is defined as the maximum particle size of the component (A). In the case where the component (A) is not spherical, that is, for example, in the case where the component (A) has a projection, the particle size of the component (A) is defined as the diameter of a circle circumscribing a conductive particle in an SEM image.

From the viewpoint of being excellent in terms of dispersibility and conductivity, the average particle size of the component (A) may be 1.0 μm or more, 2.0 μm or more, 2.5 μm or more, or 3.0 μm or more. From the viewpoint of being excellent in terms of dispersibility and conductivity, the average particle size of the component (A) may be 20.0 μm or less, 10.0 μm or less, 7.0 μm or less, or 5.0 μm or less. In this description, the particle sizes of any 300 particles (pcs) of the component (A) in the first adhesive layer are measured by observation using a scanning electron microscope (SEM), and the average of the particle sizes is defined as the average particle size.

In the first adhesive layer 1, it is preferable that the component (A) be uniformly dispersed. From the viewpoint of achieving stable connection resistance, the particle density of the component (A) in the adhesive film for circuit connection 10 may be 100 particles/mm² or more, 1000 particles/mm² or more, 3000 particles/mm² or more, 5000 particles/mm² or more, 7000 particles/mm² or more, 10000 particles/mm² or more, or 12000 particles/mm² or more. From the viewpoint of improving the insulating properties between adjacent electrodes, the particle density of the component (A) in the adhesive film for circuit connection 10 may be 100000 particles/mm² or less, 70000 particles/mm² or less, 50000 particles/mm² or less, 30000 particles/mm² or less, or 20000 particles/mm² or less.

The monodispersity of the component (A) in the adhesive film for circuit connection 10 may be 90% or more. When the monodispersity of the component (A) falls within such a range, short-circuit defects between adjacent circuits are less likely to occur, and a circuit connection structure having sufficiently high connection reliability tends to be easily obtained. The monodispersity of the component (A) may be 92% or more, 94% or more, 96% or more, 97% or more, 98% or more, or 99% or more. The upper limit of the monodispersity is 100%. The monodispersity can be determined, for example, by observing the adhesive film for circuit connection 10 at a 200-fold magnification from the first adhesive layer-side using a metallurgical microscope, measuring the number of the component (A) in the adhesive film for circuit connection 10, and calculating according to the following equation.

Monodispersity (%)=(number of conductive particles in a monodispersed state in 2500 μm²/number of conductive particles in 2500 μm²)×100

From the viewpoint of further improving conductivity, the content of the component (A) may be 1% by mass or more, 5% by mass or more, or 10% by mass or more, based on the total mass of the first adhesive layer. From the viewpoint of easily suppressing short circuiting, the content of the component (A) may be 60% by mass or less, 50% by mass or less, or 40% by mass or less, based on the total mass of the first adhesive layer. When the content of the component (A) falls within the above range, the advantageous effect of the present disclosure tends to be remarkably exhibited. The content of the component (A) in the composition or in the composition layer (based on the total mass of the composition or the composition layer) may be similar to the above range.

### [Component (B): Photocurable Resin Component]

The component (B) is not particularly limited and may be any resin component curable by light irradiation. When the component (C) is a cationically curable resin component, the component (B) may be a radically curable resin component from the viewpoint of being superior in terms of connection resistance. The component (B) may include, for example, a radically polymerizable compound (hereinafter, may be referred to as “component (B1)”) and a photoradical polymerization initiator (hereinafter, may be referred to as “component (B2)”).

### Component (B1): Radically Polymerizable Compound

The component (B1) is a compound polymerizable by a radical generated from the component (B2) upon irradiation with light (e.g., ultraviolet light). The component (B1) may be any of a monomer and a polymer (or an oligomer) obtained by polymerizing one or more monomers. Such components (B1) may be used alone or in a combination of two or more.

The component (B1) is a compound having a radically polymerizable group that undergoes a reaction by a radical. Examples of the radically polymerizable group include a (meth)acryloyl group, a vinyl group, an allyl group, a styryl group, an alkenyl group, an alkenylene group, and a maleimide group. The number of the radically polymerizable groups (the number of the functional groups) of the component (B1) may be 2 or more from the viewpoint of easily achieving a desired melt viscosity after polymerization and being superior in terms of connection reliability, and may be 10 or less, 6 or less, or 4 or less from the viewpoint of further enhancing the effect of reducing connection resistance and suppressing curing shrinkage during polymerization. In order to balance the crosslinking density with the curing shrinkage, a compound having the number of radically polymerizable groups outside the above range may also be used in addition to a compound having the number of radically polymerizable groups within the above range.

The component (B1) includes a polyfunctional (difunctional or higher-functional)(meth)acrylate, from the viewpoint of suppressing the flow of conductive particles. The polyfunctional (difunctional or higher-functional) (meth)acrylate may be a difunctional or trifunctional (meth)acrylate, and is preferably a difunctional (meth)acrylate. The difunctional (meth)acrylate may be a difunctional aromatic (meth)acrylate.

Examples of the polyfunctional (meth)acrylate include aliphatic (meth)acrylates such as ethylene glycol di(meth)acrylate, diethylene glycol di(meth)acrylate, triethylene glycol di(meth)acrylate, tetraethylene glycol di(meth)acrylate, polyethylene glycol di(meth)acrylate, propylene glycol di(meth)acrylate, dipropylene glycol di(meth)acrylate, tripropylene glycol di(meth)acrylate, tetrapropylene glycol di(meth)acrylate, polypropylene glycol di(meth)acrylate, ethoxylated polypropylene glycol di(meth)acrylate, 1,3-butanediol di(meth)acrylate, 1,4-butanediol di(meth)acrylate, neopentyl glycol di(meth)acrylate, 3-methyl-1,5-pentanediol di(meth)acrylate, 1,6-hexanediol di(meth)acrylate, 2-butyl-2-ethyl-1,3-propanediol di(meth)acrylate, 1,9-nonanediol di(meth)acrylate, 1,10-decanediol di(meth)acrylate, glycerin di(meth)acrylate, tricyclodecane dimethanol (meth)acrylate, and ethoxylated 2-methyl-1,3-propanediol di(meth)acrylate; aromatic (meth)acrylates such as ethoxylated bisphenol A-type di(meth)acrylate, propoxylated bisphenol A-type di(meth)acrylate, ethoxylated and propoxylated bisphenol A-type di(meth)acrylate, ethoxylated bisphenol F-type di(meth)acrylate, propoxylated bisphenol F-type di(meth)acrylate, ethoxylated and propoxylated bisphenol F-type di(meth)acrylate, ethoxylated fluorene-type di(meth)acrylate, propoxylated fluorene-type di(meth)acrylate, and ethoxylated and propoxylated fluorene-type di(meth)acrylate; aliphatic (meth)acrylates such as trimethylolpropane tri(meth)acrylate, ethoxylated trimethylolpropane tri(meth)acrylate, propoxylated trimethylolpropane tri(meth)acrylate, ethoxylated and propoxylated trimethylolpropane tri(meth)acrylate, pentaerythritol tri(meth)acrylate, ethoxylated pentaerythritol tri(meth)acrylate, propoxylated pentaerythritol tri(meth)acrylate, ethoxylated and propoxylated pentaerythritol tri(meth)acrylate, pentaerythritol tetra(meth)acrylate, ethoxylated pentaerythritol tetra(meth)acrylate, propoxylated pentaerythritol tetra(meth)acrylate, ethoxylated and propoxylated pentaerythritol tetra(meth)acrylate, ditrimethylolpropane tetraacrylate, and dipentaerythritol hexa(meth)acrylate; and aromatic epoxy (meth)acrylates such as bisphenol-type epoxy (meth)acrylate, phenol novolac-type epoxy (meth)acrylate, and cresol novolac-type epoxy (meth)acrylate.

The content of the polyfunctional (difunctional or higher-functional) (meth)acrylate may be, for example, 50% to 100% by mass, 70% to 100% by mass, or 90% to 100% by mass, and may also be 100% by mass, based on the total mass of the component (B1), from the viewpoint of achieving both the effect of reducing connection resistance and suppressing particle flow.

The component (B1) may further include a monofunctional (meth)acrylate in addition to the polyfunctional (difunctional or higher-functional) (meth)acrylate. Examples of the monofunctional (meth)acrylate include (meth)acrylic acid; aliphatic (meth)acrylates such as methyl (meth)acrylate, ethyl (meth)acrylate, butyl (meth)acrylate, isobutyl (meth)acrylate, tert-butyl (meth)acrylate, butoxyethyl (meth)acrylate, isoamyl (meth)acrylate, hexyl (meth)acrylate, 2-ethylhexyl (meth)acrylate, heptyl (meth)acrylate, octylheptyl (meth)acrylate, nonyl (meth)acrylate, decyl (meth)acrylate 2-hydroxyethyl (meth)acrylate, 2-hydroxypropyl (meth)acrylate, 3-chloro-2-hydroxypropyl (meth)acrylate, 2-hydroxybutyl (meth)acrylate, methoxypolyethylene glycol (meth)acrylate, ethoxypolyethylene glycol (meth)acrylate, methoxypolypropylene glycol (meth)acrylate, ethoxypolypropylene glycol (meth)acrylate, and mono (2-(meth) acryloyloxyethyl) succinate; aromatic (meth)acrylates such as benzyl (meth)acrylate, phenyl (meth)acrylate, o-biphenyl (meth)acrylate, 1-naphthyl (meth)acrylate, 2-naphthyl (meth)acrylate, phenoxyethyl (meth)acrylate, p-cumylphenoxyethyl (meth)acrylate, 0-phenylphenoxyethyl (meth)acrylate, 1-naphthoxyethyl (meth)acrylate, 2-naphthoxyethyl (meth)acrylate, phenoxypolyethylene glycol (meth)acrylate, nonylphenoxypolyethylene glycol (meth)acrylate, phenoxypolypropylene glycol (meth)acrylate, 2-hydroxy-3-phenoxypropyl (meth)acrylate, 2-hydroxy-3-(o-phenylphenoxy) propyl (meth)acrylate, 2-hydroxy-3-(1-naphthoxy) propyl (meth)acrylate, and 2-hydroxy-3-(2-naphthoxy) propyl (meth)acrylate; (meth)acrylates having an epoxy group such as glycidyl (meth)acrylate; (meth)acrylates having an alicyclic epoxy group such as 3,4-epoxycyclohexylmethyl (meth)acrylate; and (meth)acrylates having an oxetanyl group such as (3-ethyloxetan-3-yl)methyl (meth)acrylate.

The content of the monofunctional (meth)acrylate may be, for example, 0% to 50% by mass, 0% to 30% by mass, or 0% to 10% by mass, and may also be 0% by mass, based on the total mass of the component (B1).

The cured product of the component (B) may have, for example, a polymerizable group that undergoes a reaction other than by a radical. The polymerizable group that undergoes a reaction other than by a radical may be, for example, a cationically polymerizable group that undergoes a reaction by a cation. Examples of the cationically polymerizable group include an epoxy group such as a glycidyl group, an alicyclic epoxy group such as an epoxycyclohexylmethyl group, and an oxetanyl group such as an ethyloxetanylmethyl group. The cured product of the component (B) having a polymerizable group that undergoes a reaction other than by a radical can be introduced, for example, by using a (meth)acrylate having a polymerizable group that undergoes a reaction other than by a radical, such as a (meth)acrylate having an epoxy group, a (meth)acrylate having an alicyclic epoxy group, or a (meth)acrylate having an oxetanyl group, as the component (B). From the viewpoint of improving reliability, the mass ratio of the (meth)acrylate having a polymerizable group that undergoes a reaction other than by a radical relative to the total mass of the component (B1) (the mass (charge amount) of the (meth)acrylate having a polymerizable group that undergoes a reaction other than by a radical/the total mass (charge amount) of the component (B1)) may be, for example, 0 to 0.7, 0 to 0.5, or 0 to 0.3.

The component (B1) may include other radically polymerizable compounds in addition to the polyfunctional (difunctional or higher-functional) and monofunctional (meth)acrylates. Examples of the other radically polymerizable compounds include maleimide compounds, vinyl ether compounds, allyl compounds, styrene derivatives, acrylamide derivatives, and nadimide derivatives. The content of the other radically polymerizable compounds may be, for example, 0% to 40% by mass, based on the total mass of the component (B1).

### Component (B2): Photoradical Polymerization Initiator

The component (B2) is a photopolymerization initiator that generates a radical upon irradiation with light having a wavelength in the range of 150 to 750 nm, preferably light having a wavelength in the range of 254 to 405 nm, further preferably light having a wavelength of 365 nm (e.g., ultraviolet light). Such components (B2) may be used alone or in a combination of two or more.

The component (B2) decomposes upon light irradiation to generate a free radical. That is, the component (B2) is a compound that generates a radical upon receiving light energy from the outside. The component (B2) may be a compound having a structure such as an oxime ester structure, a bisimidazole structure, an acridine structure, an α-aminoalkylphenone structure, an aminobenzophenone structure, an N-phenylglycine structure, an acylphosphine oxide structure, a benzyl dimethyl ketal structure, or an α-hydroxyalkylphenone structure. Such components (B2) may be used alone or in a combination of two or more. From the viewpoint of easily achieving a desired melt viscosity and being superior in terms of the effect of reducing connection resistance, the component (B2) may be a compound having at least one structure selected from the group consisting of an oxime ester structure, an α-aminoalkylphenone structure, and an acylphosphine oxide structure.

Specific examples of the compound having an oxime ester structure include 1-phenyl-1,2-butanedione-2-(o-methoxycarbonyl) oxime, 1-phenyl-1,2-propanedione-2-(o-methoxycarbonyl) oxime, 1-phenyl-1,2-propanedione-2-(o-ethoxycarbonyl) oxime, 1-phenyl-1,2-propanedione-2-o-benzoyloxime, 1,3-diphenylpropantrione-2-(o-ethoxycarbonyl) oxime, 1-phenyl-3-ethoxypropantrione-2-(o-benzoyl) oxime, 1,2-octanedione, 1-[4-(phenylthio)phenyl-, 2-(o-benzoyloxime)], and ethanone, 1-[9-ethyl-6-(2-methylbenzoyl)-9H-carbazol-3-yl]-, 1-(o-acetyloxime).

Specific examples of the compound having an α-aminoalkylphenone structure include 2-methyl-1-[4-(methylthio)phenyl]-2-morpholinopropan-1-one, and 2-benzyl-2-dimethylamino-1-morpholinophenyl)-butanone-1.

Specific examples of the compound having an acylphosphine oxide structure include bis(2,6-dimethoxybenzoyl)-2,4,4-trimethyl-pentylphosphine oxide, bis(2,4,6,-trimethylbenzoyl)-phenylphosphine oxide, and 2,4,6-trimethylbenzoyl-diphenylphosphine oxide.

The content of the component (B2) may be, for example, 0.1 to 10 parts by mass, 0.3 to 7 parts by mass, or 0.5 to 5 parts by mass, relative to 100 parts by mass of the component (B1), from the viewpoint of suppressing flow of conductive particles.

From the viewpoint of suppressing flow of conductive particles, the content of the cured product of the component (B) may be 1% by mass or more, 5% by mass or more, or 10% by mass or more, based on the total mass of the first adhesive layer. From the viewpoint of exhibiting low resistance in low-pressure mounting, the content of the cured product of the component (B) may be 50% by mass or less, 40% by mass or less, or 30% by mass or less, based on the total mass of the first adhesive layer. When the content of the cured product of the component (B) falls within the above range, the advantageous effect of the present disclosure tends to be remarkably exhibited. The content of the component (B) in the composition or in the composition layer (based on the total mass of the composition or the composition layer) may be similar to the above range.

### [Component (C): Thermosetting Resin Component]

The component (C) is not particularly limited, and may be any resin component curable by heat. When the component (B) is a radically curable resin component, the component (C) may be a cationically curable resin component, from the viewpoint of being superior in terms of connection resistance. The component (C) may include, for example, a cationically polymerizable compound (hereinafter, may be referred to as “component (C1)”) and a thermal cationic polymerization initiator (hereinafter, may be referred to as “component (C2)”). The first thermosetting resin component and the second thermosetting resin component mean the thermosetting resin components contained in the first and second adhesive layers, respectively. The components (e.g., the components (C1) and (C2)) contained in the first and second thermosetting resin components and the contents of the components may be the same as or different from each other.

### Component (C1): Cationically Polymerizable Compound

The component (C1) is a compound that crosslinks by reacting with the component (C2) by heat. Note that the component (C1) means a compound not having a radically polymerizable group that undergoes a reaction by a radical, and the component (C1) is not included in the component (B1). Examples of the component (C1) include compounds having a cyclic ether group, such as oxetane compounds and epoxy compounds. Such components (C1) may be used alone or in a combination of two or more. From the viewpoint of further enhancing the effect of reducing connection resistance and being superior in terms of connection reliability, the component (C1) may contain, for example, at least one selected from the group consisting of an oxetane compound and an alicyclic epoxy compound. From the viewpoint of easily achieving a desired melt viscosity, the component (C1) preferably includes both at least one oxetane compound and at least one alicyclic epoxy compound.

As the oxetane compound of the component (C1), any compound that has an oxetanyl group and no radically polymerizable group may be used without particular limitation. Examples of commercially available oxetane compounds include ETERNACOLL OXBP (trade name, 4,4′-bis [(3-ethyl-3-oxetanyl) methoxymethyl]biphenyl, manufactured by Ube Industries, Ltd.), and OXSQ, OXT-121, OXT-221, OXT-101, and OXT-212 (trade names, manufactured by TOAGOSEI CO., LTD.). These compounds may be used alone or in a combination of two or more.

As the alicyclic epoxy compound of the component (C1), any compound that has an alicyclic epoxy group (e.g., an epoxycyclohexyl group) and no radically polymerizable group may be used without particular limitation. Examples of commercially available alicyclic epoxy compounds include EHPE3150, EHPE3150CE, CELLOXIDE 8010, CELLOXIDE 2021P, and CELLOXIDE 2081 (trade names, manufactured by Daicel Corporation). These compounds may be used alone or in a combination of two or more.

### Component (C2): Thermal Cationic Polymerization Initiator

The component (C2) is a thermal polymerization initiator that generates an acid or the like upon heating to initiate polymerization. The component (C2) may be a salt compound composed of a cation and an anion. Examples of the component (C2) include onium salts such as sulfonium salts, phosphonium salts, ammonium salts, diazonium salts, iodonium salts, anilinium salts, and pyridium salts, having an anion such as BF4-, BR4- (where R represents a phenyl group substituted with two or more fluorine atoms or with two or more trifluoromethyl groups), PF6-, SbF6-, or AsF6-. These may be used alone or in a combination of two or more.

From the viewpoint of storage stability, the component (C2) may be, for example, a salt compound having an anion containing boron as a constituent element, that is, BF4- or BR4- (where R represents a phenyl group substituted with two or more fluorine atoms or with two or more trifluoromethyl groups). The anion containing boron as a constituent element may be BR4-, and more specifically, may be tetrakis(pentafluorophenyl) borate.

The onium salt as the component (C2) may be, for example, an anilinium salt, because it has resistance to substances that may inhibit cationic curing. Examples of the anilinium salt compound include N,N-dialkylanilinium salts such as N,N-dimethylanilinium salts and N,N-diethylanilinium salts.

The component (C2) may be an anilinium salt having an anion containing boron as a constituent element. Examples of such salt compounds commercially available include CXC-1821 (trade name, manufactured by King Industries, Inc.).

From the viewpoint of ensuring the formability and curing properties of the first adhesive layer, the content of the component (C2) may be, for example, 0.1 to 20 parts by mass, 1 to 18 parts by mass, 3 to 15 parts by mass, or 5 to 12 parts by mass, relative to 100 parts by mass of the component (C1).

From the viewpoint of ensuring the curing properties of the first adhesive layer, the content of the component (C) may be 5% by mass or more, 10% by mass or more, 15% by mass or more, or 20% by mass or more, based on the total mass of the first adhesive layer. From the viewpoint of ensuring the formability of the first adhesive layer, the content of the component (C) may be 70% by mass or less, 60% by mass or less, 50% by mass or less, or 40% by mass or less, based on the total mass of the first adhesive layer. When the content of the component (C) falls within the above range, the advantageous effect of the present disclosure tends to be remarkably exhibited. The content of the component (C) in the composition or in the composition layer (based on the total mass of the composition or the composition layer) may be similar to the above range.

### [Other Components]

The first adhesive layer may further contain other components in addition to the component (A), the cured product of the component (B), and the component (C). Examples of the other components include a thermoplastic resin (hereinafter, may be referred to as “component (D)”), a coupling agent (hereinafter, may be referred to as “component (E)”), and a filler (hereinafter, may be referred to as “component (F)”).

Examples of the component (D) include a phenoxy resin, a polyester resin, a polyamide resin, a polyurethane resin, a polyester urethane resin, an acrylic rubber, and an epoxy resin (solid at 25° C.). These may be used alone or in a combination of two or more. When the composition containing the components (A), (B), and (C) further contains the component (D), it becomes possible to easily form a composition layer from the composition. Among these, the component (D) may be, for example, a phenoxy resin. The content of the component (D) may be 1% by mass or more, 5% by mass or more, or 10% by mass or more, and may be 70% by mass or less, 50% by mass or less, or 30% by mass or less, based on the total mass of the first adhesive layer. The content of the component (D) in the composition or in the composition layer (based on the total mass of the composition or the composition layer) may be similar to the above range.

Examples of the component (E) include a silane coupling agent having an organic functional group such as a (meth)acryloyl group, a mercapto group, an amino group, an imidazole group, or an epoxy group; a silane compound such as tetraalkoxysilane; a tetraalkoxy titanate derivative; and a polydialkyl titanate derivative. These may be used alone or in a combination of two or more. When the first adhesive layer contains the component (E), adhesiveness can be further improved. The component (E) may be, for example, a silane coupling agent. The content of the component (E) may be 0.1% to 10% by mass based on the total mass of the first adhesive layer. The content of the component (E) in the composition or in the composition layer (based on the total mass of the composition or the composition layer) may be similar to the above range.

Examples of the component (F) include a non-conductive filler (e.g., non-conductive particles). The component (F) may be either an inorganic filler or an organic filler. Examples of the inorganic filler include metal oxide fine particles such as silica fine particles, alumina fine particles, silica-alumina fine particles, titania fine particles, and zirconia fine particles; and inorganic fine particles such as metal nitride fine particles. Examples of the organic filler include organic fine particles such as silicone fine particles, methacrylate-butadiene-styrene fine particles, acrylic-silicone fine particles, polyamide fine particles, and polyimide fine particles. These may be used alone or in a combination of two or more. The component (F) may be, for example, silica fine particles. The content of the component (F) may be 0.1% to 10% by mass based on the total mass of the first adhesive layer. The content of the component (F) in the composition or in the composition layer (based on the total mass of the composition or the composition layer) may be similar to the above range.

### [Other Additives]

The first adhesive layer may further contain other additives such as a softener, an accelerator, an antidegradant, a colorant, a flame retardant, and a thixotropic agent. The content of the other additives may be, for example, 0.1% to 10% by mass, based on the total mass of the first adhesive layer. The content of the other additives in the composition or in the composition layer (based on the total mass of the composition or the composition layer) may be similar to the above range.

The thickness d1 of the first adhesive layer may be, for example, 30.0 μm or less, and may also be 20.0 μm or less, 15.0 μm or less, 10.0 μm or less, 8.0 μm or less, 5.0 μm or less, 4.5 μm or less, 4.0 μm or less, 3.5 μm or less, 3.0 μm or less, or 2.5 μm or less. When the thickness d1 of the first adhesive layer 1 is 30.0 μm or less, the amount of resin between opposing circuits becomes small, suppressing an increase in connection resistance between the opposing circuits. Such a tendency becomes more remarkable when the thickness d1 of the first adhesive layer 1 is 5.0 μm or less. The thickness d1 of the first adhesive layer 1 may be, for example, 0.1 μm or more or 0.7 μm or more. As illustrated in FIG. 1, in the case where a part of the conductive particles 4 is exposed at the surface of the first adhesive layer 1 (e.g., protrudes toward the second adhesive layer 2), the thickness of the first adhesive layer 1 is the distance (the distance illustrated by d1 in FIG. 1) from the surface 1a of the first adhesive layer 1 on the side opposite to the second adhesive layer 2 to the boundary S between the first adhesive layer 1 and the second adhesive layer 2 located at the separation portion between adjacent conductive particles 4 and 4, and the portion at which the conductive particles 4 are exposed is not included in the thickness of the first adhesive layer 1. The length of the portion at which the conductive particles 4 are exposed may be, for example, 0.1 μm or more, and may be 5.0 μm or less.

The thickness d1 of the first adhesive layer 1 can be determined, for example, by the method described in Examples. Specifically, the adhesive film for circuit connection is sandwiched between two glass plates (thickness: about 1 mm). After casting with a resin composition composed of 100 g of a bisphenol A-type epoxy resin (trade name: JER811, manufactured by Mitsubishi Chemical Corporation) and 10 g of a curing agent (trade name: Epomount curing agent, manufactured by Refine Tech Co., Ltd.), cross-sectional polishing is performed using a polishing machine, and the thickness can be measured using a scanning electron microscope (SEM, trade name: SE-8020, manufactured by Hitachi High-Tech Science Corporation). Such an operation may be conducted a plurality of times, and the average may be used as the thickness d1 of the first adhesive layer 1.

The ratio of the thickness of the first adhesive layer 1 to the average particle size of the conductive particles 4 (the thickness of the first adhesive layer 1/the average particle size of the conductive particles 4) is 0.50 or more, and may be, for example, 0.55 or more or 0.60 or more. When the above ratio is 0.50 or more, the amount of resin between opposing circuits becomes small, suppressing an increase in connection resistance between the opposing circuits. The above ratio may be, for example, 2.00 or less, 1.50 or less, 1.20 or less, or 1.00 or less.

### <Second Adhesive Layer>

The second adhesive layer 2 may be, for example, an insulating adhesive layer composed of components having no conductivity (insulating resin components). The second adhesive layer 2 contains, as second thermosetting resin components, a cationically polymerizable compound, a thermal cationic polymerization initiator, and a cation stabilizer that reacts with a cation species generated by thermal decomposition of the thermal cationic polymerization initiator.

The cationically polymerizable compound and the thermal cationic polymerization initiator contained in the second adhesive layer 2 may be similar to the component (C1) and the component (C2) used as the component (C) (i.e., the first thermosetting resin component) in the first adhesive layer 1, respectively. The cationically polymerizable compound and the thermal cationic polymerization initiator contained in the second thermosetting resin component may be the same as or different from those in the first thermosetting resin component.

From the viewpoint of maintaining reliability, the content of the second thermosetting resin component may be 5% by mass or more, 10% by mass or more, 15% by mass or more, or 20% by mass or more, based on the total mass of the second adhesive layer. From the viewpoint of preventing a resin bleeding defect in a reel, which is one supply form, the content of the second thermosetting resin component may be 80% by mass or less, 70% by mass or less, 60% by mass or less, or 50% by mass or less, based on the total mass of the second adhesive layer.

The content of the cationically polymerizable compound may be 5% by mass or more, 10% by mass or more, or 20% by mass or more, and may be 70% by mass or less, 60% by mass or less, or 50% by mass or less, based on the total mass of the second adhesive layer, from the viewpoint of maintaining reliability.

The content of the thermal cationic polymerization initiator may be, for example, 0.1 to 20 parts by mass, 1 to 18 parts by mass, 3 to 15 parts by mass, or 5 to 12 parts by mass, relative to 100 parts by mass of the cationically polymerizable compound, from the viewpoint of ensuring the formability and curing properties of the second adhesive layer.

Examples of the cation stabilizer (hereinafter, may be referred to as “component (G)”) that reacts with a cation species generated by thermal decomposition of the thermal cationic polymerization initiator include thiourea compounds, 4-alkylthiophenol compounds, and 4-hydroxyphenyl-dialkylsulfonium salts. These may be used alone or in a combination of two or more.

Examples of the thiourea compounds include ethylene thiourea, N,N′-diethylthiourea, N,N′-dibutylthiourea, and trimethylthiourea.

Examples of the 4-alkylthiophenol compounds include 4-methylthiophenol, 4-ethylthiophenol, and 4-butylthiophenol.

Examples of the 4-hydroxyphenyl-dialkylsulfonium salts include 4-hydroxyphenyl-dimethylsulfonium-methylsulfate, 4-hydroxyphenyl-diethylsulfonium-methylsulfate, and 4-hydroxyphenyl-dibutylsulfonium-methylsulfate.

The content of the component (G) may be 5 to 20 parts by mass, may be 5 to 15 parts by mass, and may be 5 to 10 parts by mass, relative to 100 parts by mass of the thermal cationic polymerization initiator.

The content of the component (G) may be 0.01% by mass or more, 0.05% by mass or more, or 0.1% by mass or more, and may be 2.0% by mass or less, 1.0% by mass or less, or 0.5% by mass or less, based on the total mass of the second adhesive layer.

The second adhesive layer 2 may further contain the other components and the other additives contained in the first adhesive layer 1. The preferable forms of the other components and the other additives are similar to those in the first adhesive layer 1.

The content of the component (D) may be 1% by mass or more, 3% by mass or more, or 5% by mass or more, and may be 60% by mass or less, 40% by mass or less, or 20% by mass or less, based on the total mass of the second adhesive layer.

The content of the component (E) may be 0.1% to 10% by mass based on the total mass of the second adhesive layer.

The content of the component (F) may be 1% by mass or more, 10% by mass or more, or 30% by mass or more, and may be 90% by mass or less, 70% by mass or less, or 50% by mass or less, based on the total mass of the second adhesive layer.

The content of the other additives may be, for example, 0.1% to 10% by mass, based on the total mass of the second adhesive layer.

The thickness d2 of the second adhesive layer 2 may be appropriately set according to, for example, the height of the electrodes of a circuit member that is to be bonded. The thickness d2 of the second adhesive layer 2 may be 5.0 μm or more or 7.0 μm or more, and may be 30.0 μm or less, 20.0 μm or less, 15.0 μm or less, or 13.0 μm or less, from the viewpoint of sealing electrodes while sufficiently filling the space between the electrodes and thereby achieving better connection reliability. In the case where a part of the conductive particles 4 is exposed at the surface of the first adhesive layer 1 (e.g., protrudes toward the second adhesive layer 2), the thickness of the second adhesive layer 2 is the distance (the distance illustrated by d2 in FIG. 1) from the surface 2a of the second adhesive layer 2 on the side opposite to the first adhesive layer 1 to the boundary S between the first adhesive layer 1 and the second adhesive layer 2 located at the separation portion between adjacent conductive particles 4 and 4.

The thickness d2 of the second adhesive layer 2 can be determined, for example, in the same manner as for the thickness d1 of the first adhesive layer 1.

The thickness of the adhesive film for circuit connection 10 (the total thickness of all the layers constituting the adhesive film for circuit connection 10, which is, in FIG. 1, the total of the thickness d1 of the first adhesive layer 1 and the thickness d2 of the second adhesive layer 2) may be, for example, 5.0 μm or more or 8.0 μm or more, and may be 60.0 μm or less, 40.0 μm or less, 30.0 μm or less, or 20.0 μm or less.

From the viewpoint of the ability to capture conductive particles, the minimum melt viscosity of the adhesive film for circuit connection 10 may be 10 Pas or more, 30 Pa·s or more, 50 Pa·s or more, or 100 Pa·s or more. From the viewpoint of connectivity between opposing electrodes, the minimum melt viscosity of the adhesive film for circuit connection 10 may be 2000 Pa·s or less, 1500 Pa·s or less, 1000 Pads or less, 500 Pa·s or less, 400 Pa·s or less, or 300 Pa·s or less. The minimum melt viscosity of the adhesive film can be determined, for example, by the following method.

### (Method for Measuring Minimum Melt Viscosity)

Adhesive films are laminated on each other with a laminator such that the thickness is 500 μm or more to form a laminate. The release-treated PET is peeled off from the laminate, and a measurement sample is obtained by cutting it to 10.0 mm×10.0 mm. The minimum melt viscosity of the measurement sample is measured using a viscoelasticity measuring device (trade name: ARES-G2, manufactured by TA Instruments, heating rate: 10° C./min).

The adhesive film for circuit connection 10 may have anisotropic conductivity and does not necessarily have anisotropic conductivity. That is, the adhesive film for circuit connection may be either an anisotropically conductive adhesive film or a non-anisotropically conductive (e.g., isotropically conductive) adhesive film. The adhesive film for circuit connection 10 may be interposed between a first circuit member having a first electrode (the surface on which the first electrode is disposed) and a second circuit member having a second electrode (the surface on which the second electrode is disposed), and may be used for thermocompression-bonding the first and second circuit members (by heating a laminate including the first circuit member, the adhesive film for circuit connection 10, and the second circuit member in a state where the laminate is pressed in its thickness direction) to electrically connect the first and second electrodes to each other (through the conductive particles (or a melt-solidified product of the conductive particles)).

According to the adhesive film for circuit connection 10, a circuit connection structure that is connected with sufficient adhesion strength and has excellent connection reliability can be obtained while the connection resistance value between opposing electrodes is reduced.

The adhesive film for circuit connection according to this embodiment has been described above. The present disclosure is not limited to the above-described embodiment. The adhesive film for circuit connection may be, for example, composed of three or more layers including the two layers, that is, the first and second adhesive layers. In this case, the adhesive film for circuit connection may further include, for example, a third adhesive layer disposed on the side of the first adhesive layer opposite to the second adhesive layer.

The third adhesive layer can contain at least the component (C). Since the components (C1) and (C2) used as the component (C) (i.e., the third thermosetting resin component) in the third adhesive layer are similar to the components (C1) and (C2) used as the component (C) (i.e., the first thermosetting resin component) in the first adhesive layer, detailed description is omitted herein. The third thermosetting resin component may be the same as or different from the first thermosetting resin component. The third thermosetting resin component may be the same as or different from the second thermosetting resin component.

From the viewpoint of imparting good transferability and peel resistance, the content of the component (C) may be 5% by mass or more, 10% by mass or more, 15% by mass or more, or 20% by mass or more, based on the total mass of the third adhesive layer. From the viewpoint of imparting good half-cutting properties and blocking resistance (suppression of resin bleeding in a reel), the content of the component (C) may be 70% by mass or less, 60% by mass or less, 50% by mass or less, or 40% by mass or less, based on the total mass of the third adhesive layer.

The third adhesive layer may further contain the other components and the other additives contained in the first adhesive layer 1. The preferable forms of the other components and the other additives are similar to those in the first adhesive layer 1.

The content of the component (D) may be 10% by mass or more, 20% by mass or more, or 30% by mass or more, and may be 80% by mass or less, 70% by mass or less, or 60% by mass or less, based on the total mass of the third adhesive layer.

The content of the component (E) may be 0.1% to 10% by mass based on the total mass of the third adhesive layer.

The content of the component (F) may be 1% by mass or more, 3% by mass or more, or 5% by mass or more, and may be 50% by mass or less, 40% by mass or less, or 30% by mass or less, based on the total mass of the third adhesive layer.

The content of the other additives may be, for example, 0.1% to 10% by mass based on the total mass of the third adhesive layer.

The thickness of the third adhesive layer may be appropriately set according to, for example, the height of electrodes of a circuit member that is to be bonded. The thickness of the third adhesive layer may be 0.2 μm or more or 0.5 μm or more, and may be 5.0 μm or less or 2.5 μm or less, from the viewpoint of sealing electrodes while sufficiently filling the space between the electrodes and thereby achieving better connection reliability. The thickness of the third adhesive layer can be determined, for example, in the same manner as for the thickness d1 of the first adhesive layer 1.

In the case where the adhesive film for circuit connection has a layer other than the first and second adhesive layers (e.g., the third adhesive layer), the thickness of the adhesive film for circuit connection (the total thickness of all the layers constituting the adhesive film for circuit connection) may be the same as the range of the thickness of the adhesive film for circuit connection 10 described above.

### <Method for Producing Adhesive Film for Circuit Connection>

A method for producing an adhesive film for circuit connection according to one embodiment may include, for example, a step (first step) of irradiating a composition layer composed of a composition containing the component (A), the component (B), the component (C) (the first thermosetting resin component), and as needed, other components with light to form a first adhesive layer, and a step (second step) of laminating a second adhesive layer containing the component (C) (the second thermosetting resin component), and as needed, other components on the first adhesive layer. The production method may further include a step (third step) of laminating a third adhesive layer containing the component (C) (the third thermosetting resin component), and as needed, other components on a layer on the side of the first adhesive layer opposite to the second adhesive layer. In this case, either the second or third step may be performed first. In the case where the third step is performed first, the third adhesive layer is laminated on the side of the first adhesive layer opposite to the side on which the second adhesive layer is to be laminated.

In the first step, for example, a composition containing the components (A), (B), and (C) and other components added as needed is dissolved or dispersed, for example, by stirring, mixing, or kneading in an organic solvent to prepare a varnish composition (a varnish-like first adhesive composition). After the varnish composition has been applied onto a release-treated substrate using a knife coater, a roll coater, an applicator, a comma coater, a die coater, or the like, the organic solvent is volatilized by heating to form a composition layer composed of the composition on the substrate. At this stage, it is possible to adjust the thickness of the final first adhesive layer (the first adhesive film) by adjusting the amount of the varnish composition applied. Subsequently, the composition layer composed of the composition is irradiated with light to cure the component (B) in the composition layer, thereby forming a first adhesive layer on the substrate. The first adhesive layer can be referred to as a first adhesive film.

The organic solvent used in the preparation of the varnish composition is not particularly limited and may be any organic solvent having a property of uniformly dissolving or dispersing each component therein. Examples of such organic solvents include toluene, acetone, methyl ethyl ketone, methyl isobutyl ketone, ethyl acetate, propyl acetate, and butyl acetate. These organic solvents can be used alone or in a combination of two or more. For performing stirring, mixing, or kneading in the preparation of the varnish composition, for example, a stirrer, a pulverizer, a three-roll mill, a ball mill, a bead mill, or a Homodisper can be used.

The substrate is not particularly limited and may be any substrate having heat resistance sufficient to withstand heating conditions for volatilizing the organic solvent. Examples of such substrates include substrates (e.g., films) made of oriented polypropylene (OPP), polyethylene terephthalate (PET), polyethylene naphthalate, polyethylene isophthalate, polybutylene terephthalate, polyolefin, polyacetate, polycarbonate, polyphenylene sulfide, polyamide, polyimide, cellulose, ethylene-vinyl acetate copolymer, polyvinyl chloride, polyvinylidene chloride, synthetic rubber-based materials, or liquid crystal polymers.

The heating conditions for volatilizing the organic solvent from the varnish composition applied to the substrate can be appropriately set according to, for example, the organic solvent used. The heating conditions may be, for example, 40° C. to 120° C. for 0.1 to 10 minutes.

Some of the solvent may remain in the first adhesive layer without being removed. The content of the solvent in the first adhesive layer may be, for example, 10% by mass or less, based on the total mass of the first adhesive layer.

For light irradiation in the curing step, it is preferable to use irradiation light including a wavelength in a range of 150 to 750 nm (e.g., ultraviolet light). The light irradiation can be performed using, for example, a low-pressure mercury lamp, a medium-pressure mercury lamp, a high-pressure mercury lamp, an ultra-high-pressure mercury lamp, a xenon lamp, a metal halide lamp, or an LED light source. The exposure dose of the light irradiation can be appropriately set; for example, it may be 500 to 3000 mJ/cm².

The second step is a step of laminating a second adhesive layer on the first adhesive layer. In the second step, for example, a second adhesive layer is formed on a substrate as in the first step to obtain a second adhesive film, except that the component (C) such as the components (C1) and (C2), the component (G), and other components added as needed are used and that no light irradiation is performed. Subsequently, the second adhesive layer can be laminated on the first adhesive layer by bonding the first and second adhesive films together. In the second step, the second adhesive layer can also be laminated on the first adhesive layer, for example, by applying a varnish composition (a varnish-like second adhesive composition) obtained using the component (C) such as the components (C1) and (C2), the component (G), and other components added as needed, onto the first adhesive layer and volatilizing the organic solvent.

Examples of methods for bonding the first and second adhesive films together include methods such as heat press, roll lamination, and vacuum lamination. The lamination can be performed, for example, under temperature conditions of 0° C. to 80° C.

Some of the solvent may remain in the second adhesive layer without being removed. The content of the solvent in the second adhesive layer may be, for example, 10% by mass or less based on the total mass of the second adhesive layer.

The third step is a step of laminating a third adhesive layer on a layer on the side of the first adhesive layer opposite to the second adhesive layer. In the third step, for example, a third adhesive layer is formed on a substrate as in the second step to obtain a third adhesive film. Subsequently, the third adhesive layer can be laminated on a layer on the side of the first adhesive layer opposite to the second adhesive layer, by bonding the third adhesive film to the side of the first adhesive film opposite to the second adhesive film. In third step, the third adhesive layer can also be laminated on the first adhesive layer, for example, as in the second step, by applying a varnish composition (a varnish-like third adhesive composition) onto a layer on the side of the first adhesive layer opposite to the second adhesive layer and volatilizing the organic solvent. The method and conditions for the bonding are similar to those in the second step.

Some of the solvent may remain in the third adhesive layer without being removed. The content of the solvent in the third adhesive layer may be, for example, 10% by mass or less based on the total mass of the third adhesive layer.

### <Circuit Connection Structure and Method for Producing the Same>

A circuit connection structure and a method for producing the circuit connection structure will be described below by taking, as an example, an embodiment in which the above-described adhesive film for circuit connection 10 is used as a circuit connection material.

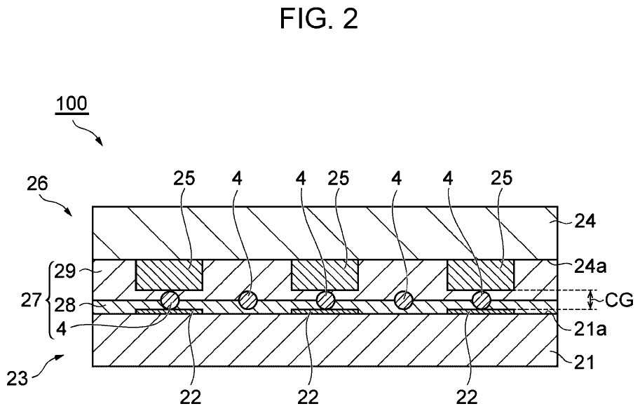

FIG. 2 is a schematic cross-sectional view of one embodiment of the circuit connection structure. As illustrated in FIG. 2, a circuit connection structure 100 includes a first circuit member 23 having a first circuit board 21 and a first electrode 22 disposed on a main surface 21a of the first circuit board 21; a second circuit member 26 having a second circuit board 24 and a second electrode 25 disposed on a main surface 24a of the second circuit board 24; and a circuit connection portion 27 that contains a cured body of the adhesive film for circuit connection 10, is disposed between the first circuit member 23 and the second circuit member 26, electrically connects the first electrode 22 and the second electrode 25 to each other through the conductive particles 4 (or a melt-solidified product of the conductive particles 4), and bonds the first circuit member 23 and the second circuit member 26.

The first circuit member 23 and the second circuit member 26 may be the same as or different from each other. The first circuit member 23 and the second circuit member 26 may be, for example, a glass or plastic substrate on which electrodes are formed, a printed wiring board, a ceramic wiring board, a flexible wiring board, or an IC chip. The first circuit board 21 and the second circuit board 24 may be formed of, for example, an inorganic material such as a semiconductor, glass, or ceramic, an organic material such as polyimide or polycarbonate, or a composite material such as glass/epoxy. Among these, for the purpose of suitably using the adhesive film for circuit connection 10A for COP mounting, the first circuit member 23 may be, for example, a plastic substrate made of an organic material such as polyimide, polycarbonate, polyethylene terephthalate, or cycloolefin polymer, and the second circuit board 24 may be, for example, an IC chip.

The first electrode 22 and the second electrode 25 may be electrodes containing, for example, metals such as gold, silver, tin, ruthenium, rhodium, palladium, osmium, iridium, platinum, copper, aluminum, molybdenum, and titanium, or oxides such as indium tin oxide (ITO), indium zinc oxide (IZO), and indium gallium zinc oxide (IGZO). The first electrode 22 and the second electrode 25 may also be electrodes formed by stacking two or more of these metals, oxides, and the like. The electrodes formed by stacking two or more such materials may have two or more layers and may have three or more layers. In the case where the first circuit member 23 is a plastic substrate, the first electrode 22 may be an electrode having a titanium layer on the outermost surface. The first electrode 22 and the second electrode 25 may be circuit electrodes and may also be bump electrodes. At least one of the first electrode 22 and the second electrode 25 may be a bump electrode. The circuit connection structure illustrated in FIG. 2 is an embodiment in which the first electrode 22 is a circuit electrode and the second electrode 25 is a bump electrode.

The circuit connection portion 27 includes a cured body of the adhesive film for circuit connection 10. The circuit connection portion 27 may be formed of a cured body of the adhesive film for circuit connection 10. The circuit connection portion 27 has, for example, a first cured body region 28 located on the first circuit member 23-side in the direction (hereinafter, “facing direction”) in which the first circuit member 23 and the second circuit member 26 face each other and formed of a cured body derived from the first adhesive layer other than the conductive particles 4; a second cured body region 29 located on the second circuit member 26-side in the facing direction and formed of a cured body derived from the second adhesive layer; and the conductive particles 4 at least interposed between the first electrode 22 and the second electrode 25 to electrically connect the first electrode 22 and the second electrode 25 to each other. The circuit connection portion 27 does not necessarily have two distinct cured body regions, that is, the first cured body region 28 and the second cured body region 29, as illustrated in FIG. 2, and may have a single cured body region in which a cured body derived from the first adhesive layer and a cured body derived from the second adhesive layer are mixed.

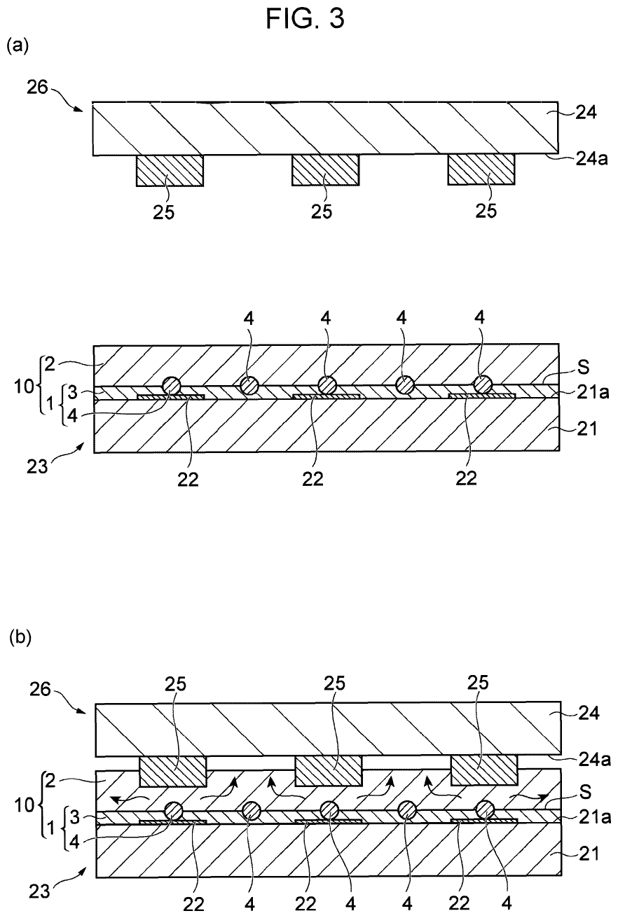

FIG. 3 includes schematic cross-sectional views of one embodiment of the method for producing a circuit connection structure. FIGS. 3(a) and 3(b) are schematic cross-sectional views illustrating respective steps. As illustrated in FIG. 3, the method for producing a circuit connection structure 100 includes a step of interposing an adhesive film for circuit connection 10 between a first circuit member 23 having a first electrode 22 and a second circuit member 26 having a second electrode 25, and thermocompression-bonding the first circuit member 23 and the second circuit member 26 to electrically connect the first electrode 22 and the second electrode 25 to each other.

Specifically, a first circuit member 23 including a first circuit board 21 and a first electrode 22 formed on a main surface 21a of the first circuit board 21, and a second circuit member 26 including a second circuit board 24 and a second electrode 25 formed on a main surface 24a of the second circuit board 24, are prepared.

The first circuit member 23 and the second circuit member 26 are arranged such that the first electrode 22 and the second electrode 25 face each other, and the adhesive film for circuit connection 10 is disposed between the first circuit member 23 and the second circuit member 26. For example, as illustrated in FIG. 3(a), the adhesive film for circuit connection 10 is laminated on the first circuit member 23 such that the first adhesive layer 1-side faces the main surface 21a of the first circuit board 21. Subsequently, the second circuit member 26 is disposed on the first circuit member 23 on which the adhesive film for circuit connection 10 has been laminated, such that the first electrode 22 on the first circuit board 21 and the second electrode 25 on the second circuit board 24 face each other.

As illustrated in FIG. 3(b), while the first circuit member 23, the adhesive film for circuit connection 10A, and the second circuit member 26 are heated, the first circuit member 23 and the second circuit member 26 are pressed in the thickness direction to thermocompression-bond the first circuit member 23 and the second circuit member 26 to each other. At this stage, as indicated by the arrows in FIG. 3(b), since the second adhesive layer 2 has an uncured flowable thermosetting resin component, it flows so as to fill gaps between the second electrodes 25 and cures by heating during the thermocompression bonding. As a result, the first electrode 22 and the second electrode 25 are electrically connected to each other through the conductive particles 4, and the first circuit member 23 and the second circuit member 26 are bonded to each other, thereby obtaining the circuit connection structure 100 illustrated in FIG. 2.

In the method for producing the circuit connection structure 100 according to this embodiment, the first adhesive layer 1 can be regarded as a layer partially cured by light irradiation, and the conductive particles 4 are fixed in the first adhesive layer 1. Since the first adhesive layer 1 hardly flows during the thermocompression bonding and the conductive particles are efficiently captured between the opposing electrodes, the connection resistance between the first electrode 22 and the second electrode 25 opposing each other can be reduced. Furthermore, using the adhesive film for circuit connection 10 having the second adhesive layer containing a cation stabilizer improves the resin exclusion properties and reduces the connection gap (the distance between the connected opposing electrodes) (CG in FIG. 2). This increases the contact area between the conductive particles and the electrodes, and further reduces the connection resistance between the first electrode 22 and the second electrode 25 opposing each other. Moreover, when the thickness of the first adhesive layer is 5.0 μm or less, the amount of resin between opposing circuits becomes small, and an increase in connection resistance between the opposing circuits can be further suppressed.

The heating temperature during the thermocompression bonding can be appropriately set and may be, for example, 50° C. to 250° C. The pressure is not particularly limited and may be any pressure that does not cause damage to the adherend. In COP mounting, for example, the pressure converted on the basis of the area of the bump electrode may be 10 to 50 MPa, and may also be 0.1 to 40 MPa. In the case of COG mounting, for example, the pressure converted on the basis of the area of the bump electrode may be 10 to 100 MPa. The time for the heating and pressing may be 0.5 to 120 seconds.

From the viewpoint of ensuring good connection characteristics, the connection temperature for thermocompression-bonding the first and second circuit members may be 170° C. to 220° C., and the thermocompression bonding may be performed such that the temperature reaches 80% or more of the connection temperature one second after the start of heating. Even in such a case, the use of the adhesive film for circuit connection 10 can sufficiently reduce the connection gap CG, thereby achieving both a reduction in connection resistance, and good connection reliability and adhesion strength.

### EXAMPLES

The present disclosure will be described more specifically with reference to Examples below. It should be noted that the present disclosure is not limited to these Examples.

In Examples and Comparative Examples, the following materials were used as component (A), component (B1), component (B2), component (C1), component (C2), component (D), component (E), component (F), and component (G).

### Component (A): Conductive Particles

Conductive particles A-1: Particles having an average particle size of 3.2 μm, obtained by plating the surface of a plastic core with Ni and further subjecting the outermost surface to displacement plating with Pd. Particle hardness: 10,000 to 18,000 N/mm²

Conductive particles A-2: Particles having an average particle size of 3.2 μm, obtained by plating the surface of a plastic core with Ni and further subjecting the outermost surface to displacement plating with Pd. Particle hardness: 5,000 to 9,000 N/mm²

### Component (B): Photocurable Resin Component

### Component (B1): Radically Polymerizable Compound

Radically polymerizable compound B1-1: VR-90 (bisphenol A-type epoxy (meth)acrylate (difunctional) (vinyl ester resin), manufactured by Resonac Corporation)

Radically polymerizable compound B1-2: A-1000 (polyethylene glycol diacrylate (difunctional), manufactured by SHIN-NAKAMURA CHEMICAL Co., Ltd.)

### Component (B2): Photoradical Polymerization Initiator

Photoradical polymerization initiator B2-1: “Omnirad 907 (a compound having an α-aminoalkylphenone structure, manufactured by IGM Resins)”

### Component (C): Thermosetting Resin Component

### Component (C1): Cationically Polymerizable Compound

Cationically polymerizable compound C1-1: ETERNACOLL OXBP (oxetane compound, manufactured by Ube Industries, Ltd.)

Cationically polymerizable compound C1-2: EHPE3150 (alicyclic epoxy compound, manufactured by Daicel Corporation)

Cationically polymerizable compound C1-3: CELLOXIDE 2021P (alicyclic epoxy compound, manufactured by Daicel Corporation)

Cationically polymerizable compound C1-4: jER1007 (epoxy compound, manufactured by Mitsubishi Chemical Corporation)

### Component (C2): Thermal Cationic Polymerization Initiator

Thermal cationic polymerization initiator C2-1: CXC-1821 (N-(p-methoxybenzyl)-N,N-dimethylanilinium tetrakis(pentafluorophenyl) borate, manufactured by King Industries, Inc.)

### Component (D): Thermoplastic Resin

Thermoplastic resin D-1: Phenotohto FX-293 (phenoxy resin, manufactured by NIPPON STEEL Chemical & Material Co., Ltd.)

Thermoplastic resin D-2: Phenotohto YP-70 (phenoxy resin, manufactured by NIPPON STEEL Chemical & Material Co., Ltd.)

### Component (E): Coupling Agent

Coupling agent E-1: SH-6040 (3-glycidoxypropyltrimethoxysilane, manufactured by Toray Dow Corning Co., Ltd.)

### Component (F): Filler

Filler F-1: Admafine SE2050 (silica fine particles, manufactured by Admatechs Co., Ltd.)

Filler F-2: AEROSIL R805 (silica fine particles, manufactured by Evonik Industries AG)

### Component (G): Cation Stabilizer

Stabilizer G-1:4-hydroxyphenyl-dimethylsulfonium-methylsulfate (manufactured by Sika Hamatite Co., Ltd.)

### <Preparation of First Adhesive Layer>

### (Adhesive Layers P-1 and P-2)

The materials shown in Table 1 were mixed with MEK in the compounding ratios shown in Table 1 (the numerical values in Table 1 mean nonvolatile content) to obtain varnish compositions (nonvolatile content concentration: 50% by mass). Each varnish composition was applied to a release-treated PET (polyethylene terephthalate) film while a magnetic field was applied, and the organic solvent and the like were hot-air dried at 70° C. for 5 minutes to obtain composition layers composed of respective compositions containing each component. The application was performed such that the thickness of each composition layer became 3.5 μm after drying. Subsequently, each composition layer was irradiated with light (UV irradiation: metal halide lamp, exposure dose: 1500 to 2500 mJ/cm²) to prepare first adhesive layers in which conductive particles were dispersed. The thickness here was measured using a contact-type thickness meter.

When the thickness of the first adhesive layer is smaller than the thickness (diameter) of the conductive particles, measurement of the thickness of the layer using a contact-type thickness meter reflects the thickness of the conductive particles, and the thickness of the region in which the conductive particles are present is measured. Therefore, after the preparation of an adhesive film having a two-layer structure in which the first and second adhesive layers were laminated, the thickness of a portion of the first adhesive layer located at the separation portion between adjacent conductive particles was measured using a scanning electron microscope by the following method. Table 1 shows the results.

### [Measuring Method]

The adhesive film was sandwiched between two glass plates (thickness: about 1 mm). After casting with a resin composition composed of 100 g of a bisphenol A-type epoxy resin (trade name: JER811, manufactured by Mitsubishi Chemical Corporation) and 10 g of a curing agent (trade name: Epomount curing agent, manufactured by Refine Tech Co., Ltd.), cross-sectional polishing was performed using a polishing machine, and the thickness of each layer was measured using a scanning electron microscope (SEM, trade name: SE-8020, manufactured by Hitachi High-Tech Science Corporation).

When the projected particle density of each first adhesive layer was measured, it was about 18000 particles/mm².

TABLE 1

| | | Adhesive layer P-1 | Adhesive layer P-2 |
|---|---|---|---|
| Component (A) | A-1 | 45 | — |
| | A-2 | — | 45 |
| Component (B1) | B1-1 | 10 | 10 |
| | B1-2 | 10 | 10 |
| Component (B2) | B2-1 | 0.5 | 0.5 |
| Component (C1) | C1-1 | 30 | 30 |
| | C1-2 | 10 | 10 |
| Component (C2) | C2-1 | 4 | 4 |
| Component (D) | D-1 | 20 | 20 |
| | D-2 | 20 | 20 |
| Component (E) | E-1 | 3 | 3 |

| | | |
|---|---|---|
| Thickness (μm) | 2.0 | 2.0 |

### <Preparation of Second Adhesive Layer>

The materials shown in Table 2 were mixed with MEK in the compounding ratio shown in Table 2 (the numerical values in Table 2 mean nonvolatile content) to obtain varnish compositions (nonvolatile content concentration: 60% by mass). Each varnish composition was applied to a release-treated PET (polyethylene terephthalate) film, and the organic solvent and the like were hot-air dried at 70° C. for 5 minutes to obtain second composition layers composed of respective compositions containing each component. The application was performed such that the thickness of each composition layer became the thickness shown in Table 2 after drying. The thickness here was measured using a contact-type thickness meter.

TABLE 2

| | | Adhesive layer | Adhesive layer | Adhesive layer | Adhesive layer | Adhesive layer | Adhesive layer |
|---|---|---|---|---|---|---|---|
| | | S-1 | S-2 | S-3 | S-4 | S-5 | S-6 |
| Component (C1) | C1-1 | 20 | 20 | 20 | 20 | 20 | 20 |
| | C1-2 | 10 | 10 | 10 | 10 | 50 | 10 |
| | C1-3 | 20 | 20 | 20 | 20 | 20 | 20 |
| | C1-4 | 30 | 30 | 30 | 30 | 30 | 30 |
| Component (C2) | C2-1 | 4 | 4 | 4 | 4 | 4 | 4 |
| Component (D) | D-2 | 20 | 20 | 20 | 20 | 20 | 20 |
| Component (E) | E-1 | 3 | 3 | 3 | 3 | 3 | 3 |
| Component (F) | F-1 | 80 | 80 | 80 | 80 | — | 80 |
| | F-2 | 5 | 5 | 5 | 5 | 5 | 5 |
| Component (G) | G-1 | 0.2 | 0.4 | 0.6 | — | — | — |

| | | | | | | |
|---|---|---|---|---|---|---|
| Thickness (μm) | 6 | 6 | 6 | 6 | 6 | 4 |

### Examples 1 to 4 and Comparative Examples 1 to 4

### [Preparation of Adhesive Films]

Adhesive films having the structures shown in Table 3 were prepared using the first and second adhesive layers prepared above. For example, in the adhesive film of Example 1, a first adhesive layer formed using the composition P-1 was laminated onto a second adhesive layer formed using the composition S-1 while applying a temperature of 50° C. to 60° C., to obtain the adhesive film of Example 1. For the adhesive films of Examples 2 to 4 and Comparative Examples 1 to 4, adhesive films having the structures shown in Table 3 were prepared as in Example 1.

### [Measurement of Minimum Melt Viscosity]

Adhesive films were laminated on each other with a laminator such that the thickness was 500 μm or more to form a laminate. The release-treated PET was peeled off from the laminate, and a measurement sample was obtained by cutting it to 10.0 mm×10.0 mm. The minimum melt viscosity of the measurement sample was measured using a viscoelasticity measuring device (trade name: ARES-G2, manufactured by TA Instruments, heating rate: 10° C./min).

### [Preparation of Circuit Connection Structures]

Circuit connection structures were prepared by the following procedure using the adhesive films for circuit connection of Examples 1 to 4 and Comparative Examples 1 to 4.

As a first circuit member, a plastic substrate (thickness: 0.05 mm) having a Ti/Al/Ti circuit was prepared. As a second circuit member, an IC chip having gold bumps (the area of the bump electrodes: 840 μm², the space (pitch) between the bump electrodes: 24 μm, the height of the bump electrodes: 8 μm) was prepared.

The adhesive film for circuit connection was cut to a width of 2.0 mm. The adhesive film for circuit connection was then placed on the first circuit member such that the first adhesive layer was in contact with the first circuit member. Using a thermocompression pre-bonding apparatus (LD-06, manufactured by OHASHI ENGINEERING Co., Ltd.) composed of a stage formed of a ceramic heater and a tool (8 mm×50 mm), heating and pressing were performed at 70° C. and 0.98 MPa (10 kgf/cm²) for 2 seconds to bond the adhesive film for circuit connection to the first circuit member. The release film on the side of the adhesive film for circuit connection opposite to the first circuit member was peeled. Subsequently, after aligning the circuit electrodes of the first circuit member with the bump electrodes of the second circuit member, heating and pressing were performed at a connection temperature of 180° C. and a pressure of 20 MPa, which was converted on the basis of the area of the bump electrode, for 5 seconds using an 8 mm×45 mm heat tool with a Teflon (registered trademark) sheet having a thickness of 50 μm interposed as a buffer material, to prepare a circuit connection structure.

### (Measurement of Connection Gap)

The entire circuit connection structure prepared above was sealed with a casting resin composed of 100 parts by mass of a bisphenol A-type epoxy resin (trade name: JER811, manufactured by Mitsubishi Chemical Corporation) and 10 parts by mass of a curing agent (trade name: Epomount curing agent, manufactured by Refine Tech Co., Ltd.) to prepare a casting sample. The casting sample was polished with a polishing machine (manufactured by Refine Tech Co., Ltd.) to prepare a cross-sectional sample capable of observing the cross section of the circuit connection structure. For the prepared cross-sectional sample, the distance between the bump electrodes and the circuit electrodes was measured at a 10000-fold magnification using a scanning electron microscope (SU8000, manufactured by Hitachi High-Tech Science Corporation).

### (Evaluation of Connection Resistance: Initial)

The initial connection resistance (conduction resistance) of the circuit connection structure prepared was measured by a four-terminal method. In the measurement, a constant current (1 mA) was applied between the circuit electrodes of the first and second circuit members (connection portion) of the circuit connection structure using a constant current power supply device R-6145 manufactured by Advantest Corporation. The potential difference of the connection portion at the time of current application was measured using a digital multimeter (R-6557) manufactured by Advantest Corporation. The potential difference was measured at any 14 points, and the average was calculated and evaluated based on the following criteria.
A: less than 0.8 Ω
B: 0.8Ω or more and less than 1.0 Ω
C: 1.0Ω or more

### (Evaluation of Connection Resistance: After Reliability Test)

The circuit connection structure prepared was stored under an environment of 110° C. and 85% RH for 64 hours. Subsequently, in the same manner as described above, the average potential difference of the connection portion was calculated and evaluated based on the following criteria.
A: less than 0.8 Ω
B: 0.8Ω or more and less than 1.2 Ω
C: 1.2Ω or more

### [Adhesion Strength]

As a first circuit member, a glass substrate (thickness: 0.5 mm) with SiN (silicon nitride) was prepared. As a second circuit member, an IC chip having gold bumps (the area of the bump electrodes: 840 μm², the space (pitch) between the bump electrodes: 24 μm, the height of the bump electrodes: 8 μm) was prepared.

The adhesive film for circuit connection was cut to a width of 2.0 mm. The adhesive film for circuit connection was then placed on the first circuit member such that the first adhesive layer was in contact with the first circuit member. Using a thermocompression pre-bonding apparatus (LD-06, manufactured by OHASHI ENGINEERING Co., Ltd.) composed of a stage formed of a ceramic heater and a tool (8 mm×50 mm), heating and pressing were performed at 70° C. and 0.98 MPa (10 kgf/cm²) for 2 seconds to bond the adhesive film for circuit connection to the first circuit member. The release film on the side of the adhesive film for circuit connection opposite to the first circuit member was peeled. Subsequently, after aligning the circuit electrodes of the first circuit member with the bump electrodes of the second circuit member, heating and pressing were performed at a connection temperature of 180° C. and a pressure of 20 MPa, which was converted on the basis of the area of the bump electrode, for 5 seconds using an 8 mm×45 mm heat tool with a Teflon (registered trademark) sheet having a thickness of 50 μm interposed as a buffer material, to prepare a circuit connection structure.

For the circuit connection structure prepared, the shear strength at the time of peeling the IC chip from the glass substrate (peeling speed: 16 μm/s, temperature: 25° C.) was measured using a shear adhesion tester (4000Plus, manufactured by Nordson Advanced Technology) and evaluated based on the following criteria.
A: shear strength of 35 MPa or more
B: shear strength of 30 MPa or more and less than 35 MPa
C: shear strength of less than 30 MPa

TABLE 3

| | | | | | | Comparative | Comparative | Comparative | Comparative |
|---|---|---|---|---|---|---|---|---|---|
| | | Example 1 | Example 2 | Example 3 | Example 4 | Example 1 | Example 2 | Example 3 | Example 4 |
| First adhesive layer | | P-1 | P-2 | P-1 | P-1 | P1 | P-1 | P-1 | P-2 |
| Second adhesive layer | | S1 | S-1 | S-2 | S-3 | S-5 | S-6 | S-4 | S-4 |
| Minimum melt viscosity | | 250 | 250 | 250 | 200 | 250 | 500 | 500 | 500 |
| (Pa · s) | | | | | | | | | |
| Connection gap (μm) | | 1.8 | 1.8 | 1.7 | 1.9 | 2.2 | 2.2 | 2.2 | 2.2 |
| Connection | Initial | A | A | A | B | B | A | B | C |
| resistance | After | A | A | A | B | C | C | C | C |
| | reliability | | | | | | | | |
| | test | | | | | | | | |

| | | | | | | | | |
|---|---|---|---|---|---|---|---|---|
| Adhesion strength | A | A | A | A | A | C | A | A |

### REFERENCE SIGNS LIST

1: first adhesive layer, 2: second adhesive layer, 3: adhesive component, 4: conductive particles, 10: adhesive film for circuit connection, 21: first circuit board, 22: first electrode (circuit electrode), 23: first circuit member, 24: second circuit board, 25: second electrode (bump electrode), 26: second circuit member, 27: circuit connection portion, 100: circuit connection structure.

1. A method for producing a circuit connection structure, the method comprising a step of interposing an adhesive film for circuit connection containing conductive particles between a first circuit member having a first electrode and a second circuit member having a second electrode, and thermocompression-bonding the first circuit member and the second circuit member to electrically connect the first electrode and the second electrode to each other,
wherein the adhesive film for circuit connection has a first adhesive layer comprising conductive particles and a first thermosetting resin component, and a second adhesive layer disposed on the first adhesive layer, the second adhesive layer comprising a second thermosetting resin component, and
wherein the second thermosetting resin component includes a cationically polymerizable compound, a thermal cationic polymerization initiator, and a cation stabilizer that reacts with a cation species generated by thermal decomposition of the thermal cationic polymerization initiator.

2. The method for producing a circuit connection structure according to claim 1, wherein the cation stabilizer is at least one compound selected from the group consisting of a thiourea compound, a 4-alkylthiophenol compound, and a 4-hydroxyphenyl-dialkylsulfonium salt.

3. The method for producing a circuit connection structure according to claim 1, wherein a content of the cation stabilizer in the second adhesive layer is 5 to 20 parts by mass, relative to 100 parts by mass of the thermal cationic polymerization initiator.

4. The method for producing a circuit connection structure according to claim 1, wherein a content of the cation stabilizer in the second adhesive layer is 0.01% to 2.0% by mass, based on a total mass of the second adhesive layer.

5. The method for producing a circuit connection structure according to claim 1, wherein the cationically polymerizable compound is at least one compound selected from the group consisting of an oxetane compound and an alicyclic epoxy compound.

6. The method for producing a circuit connection structure according to claim 1, wherein the first thermosetting resin component includes a cationically polymerizable compound and a thermal cationic polymerization initiator,
wherein the first adhesive layer further comprises a cured product of a photocurable resin component, and
wherein the photocurable resin component includes a radically polymerizable compound and a photoradical polymerization initiator.

7. The method for producing a circuit connection structure according to claim 1, wherein the first adhesive layer has a thickness of 5.0 μm or less.

8. An adhesive film for circuit connection, the adhesive film comprising a first adhesive layer comprising conductive particles and a first thermosetting resin component, and a second adhesive layer disposed on the first adhesive layer, the second adhesive layer comprising a second thermosetting resin component,
wherein the second thermosetting resin component includes a cationically polymerizable compound, a thermal cationic polymerization initiator, and a cation stabilizer that reacts with a cation species generated by thermal decomposition of the thermal cationic polymerization initiator.

9. The adhesive film for circuit connection according to claim 8, wherein the cation stabilizer is at least one compound selected from the group consisting of a thiourea compound, a 4-alkylthiophenol compound, and a 4-hydroxyphenyl-dialkylsulfonium salt.

10. The adhesive film for circuit connection according to claim 8, wherein a content of the cation stabilizer in the second adhesive layer is 5 to 20 parts by mass, relative to 100 parts by mass of the thermal cationic polymerization initiator.

11. The adhesive film for circuit connection according to claim 8, wherein a content of the cation stabilizer in the second adhesive layer is 0.01% to 2.0% by mass, based on a total mass of the second adhesive layer.

12. The adhesive film for circuit connection according to claim 8, wherein the cationically polymerizable compound is at least one compound selected from the group consisting of an oxetane compound and an alicyclic epoxy compound.

13. The adhesive film for circuit connection according to claim 8, wherein the first thermosetting resin component includes a cationically polymerizable compound and a thermal cationic polymerization initiator,
wherein the first adhesive layer further comprises a cured product of a photocurable resin component, and
wherein the photocurable resin component includes a radically polymerizable compound and a photoradical polymerization initiator.

14. The adhesive film for circuit connection according to claim 8, wherein the first adhesive layer has a thickness of 5.0 μm or less.

15. A circuit connection structure comprising:
a first circuit member having a first electrode;
a second circuit member having a second electrode; and
a circuit connection portion disposed between the first circuit member and the second circuit member, the circuit connection portion electrically connecting the first electrode and the second electrode to each other,
wherein the circuit connection portion includes a cured body of the adhesive film for circuit connection according to claim 8.
